(19) United States
(12) Patent Application Publication
(10) Pub. No.: US 2025/0015167 A1
(43) Pub. Date: Jan. 9, 2025

(54) MULTI-GATE DEVICE AND RELATED METHODS

(71) Applicant: Taiwan Semiconductor Manufacturing Company, Ltd., Hsinchu (TW)

(72) Inventors: Wen-Yi LIN, Tainan County (TW); Shi-Sheng HU, Tainan City (TW); Chung-Hao CHU, Hsinchu (TW); Chao-Chi CHEN, Tainan City (TW)

(21) Appl. No.: 18/348,780

(22) Filed: Jul. 7, 2023

(51) Int. Cl. H01L 29/66; H01L 21/8238; H01L 27/092; H01L 29/06; H01L 29/08; H01L 29/423; H01L 29/775; H01L 29/78

(52) U.S. Cl. CPC H01L 29/66795; H01L 21/823807; H01L 21/823821; H01L 27/0924; H01L 29/0673; H01L 29/0847; H01L 29/42392; H01L 29/66439; H01L 29/66545; H01L 29/775; H01L 29/7851

(57) ABSTRACT

A method of fabricating a semiconductor device includes providing a first fin extending from a substrate. In some embodiments, the method further includes forming a first gate stack over the first fin. In various examples, the method further includes forming a first doped layer along a surface of the first fin including beneath the first gate stack. In some cases, a first dopant species of the first doped layer is of a same polarity as a second dopant species of a source/drain feature of the semiconductor device.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As merely one example, fabricating transistors having a low density of interface traps and oxide traps is vital to providing high-performance devices. However, with the continued scaling of IC dimensions and the introduction of multi-gate devices (e.g., such as fin field-effect transistors (FinFETs)), the challenges have increased. One particular challenge is noise, such as flicker (1/f) noise, which may be caused by interface and oxide traps, and which can degrade device performance. Moreover, given the increased proportion of transistor channel-to-gate dielectric interface surface area for multi-gate devices, the occurrence of charge trapping of carriers at the channel-to-gate dielectric interface may only increase.

Thus, existing techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates an exemplary MOS transistor, in accordance with some embodiments;

FIG. 1B illustrates an exemplary multi-gate transistor, in accordance with some embodiments;

FIG. 2 is a flow chart of a method of fabricating a multi-gate device according to one or more aspects of the present disclosure;

FIGS. 3A, 4A, 9A, 10A, and 12A provide isometric views of a GAA device 300A fabricated according to aspects of the method of FIG. 2;

FIGS. 3B, 4B, 9B, 10B, and 12B provide isometric views of a FinFET device 300B fabricated according to aspects of the method of FIG. 2;

FIGS. 5A, 5B, 7A, and 7B provide cross-section views of the FinFET device 300B along a plane parallel to section Y1-Y1′, as shown in FIG. 4B;

FIGS. 6A, 6B, 8A, 8B, and 8C provide cross-sections views of the FinFET device 300B along a plane parallel to section X1-X1′, as shown in FIG. 4B;

FIGS. 10C and 10D provide cross-sections views of the GAA device 300A and the FinFET device 300B, respectively, along a plane parallel to sections X2-X2′, as shown in FIGS. 10A and 10B;

FIGS. 10E and 10F provide cross-sections views of the GAA device 300A and the FinFET device 300B, respectively, along a plane parallel to sections Y2-Y2′, as shown in FIGS. 10A and 10B;

FIGS. 11A and 11B provide enlarged views of a portion of the GAA device 300A, as shown in FIG. 10E;

FIG. 12C provides a cross-section view of the GAA device 300A along a plane parallel to section X2-X2′, as shown in FIG. 10A;

FIG. 12E provides a cross-sections view of the GAA device 300A along a plane parallel to section Y2-Y2′, as shown in FIG. 10A;

FIG. 12D provides a cross-section view of the FinFET device 300B along a plane parallel to section X2-X2′, as shown in FIG. 10B;

FIG. 12F provides a cross-sections view of the FinFET device 300B along a plane parallel to section Y2-Y2′, as shown in FIG. 10B; and

FIG. 12G provides a zoomed-in cross-section view of a portion of FIG. 12E, which more clearly illustrates the structure and sizes of various aspects of the GAA device 300A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

It is also noted that the present disclosure presents embodiments in the form of a method and related structure which may be employed in any of a variety of device types. For example, embodiments of the present disclosure may be used in the fabrication of planar bulk metal-oxide-semiconductor field-effect transistors (MOSFETs), multi-gate transistors (planar or vertical) such as FinFET devices, gate-all-around (GAA) devices, Omega-gate (Ω-gate) devices, or Pi-gate (Π-gate) devices, as well as strained-semiconductor devices, silicon-on-insulator (SOI) devices, partially-depleted SOI devices, fully-depleted SOI devices, or other devices as known in the art. In addition, embodiments disclosed herein may be employed in the formation of P-type and/or N-type devices. One of ordinary skill may recognize other embodiments of semiconductor devices that may benefit from aspects of the present disclosure.

In advanced semiconductor processing, fabricating transistors having a low density of interface traps and oxide traps is vital to providing high-performance devices. However, with the continued scaling of IC dimensions and the introduction of multi-gate devices (e.g., such as FinFETs), the challenges have increased. One particular challenge is noise, such as flicker (1/f) noise, which may be caused by interface and oxide traps, and which can degrade device performance. Moreover, given the increased proportion of transistor channel-to-gate dielectric interface surface area for multi-gate devices, the occurrence of charge trapping of carriers at the channel-to-gate dielectric interface may only increase. As a result, existing techniques have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures for reducing noise (e.g., such as flicker noise) for advanced transistor structures. Generally, the disclosed embodiments may effectively reduce flicker noise by improving (reducing) the density of interface traps and oxide traps, as well as by modulating a transistor channel current path (e.g., a current path between a source and a drain of the transistor) such that the current path is a distance (e.g., greater than about 2 Angstroms) away from the transistor channel-to-gate dielectric interface, thereby minimizing the occurrence of charge trapping at the channel-to-gate dielectric interface. In some embodiments, the reduction of traps may be accomplished by use of a post-deposition anneal (PDA) process (e.g., performed after formation of the gate dielectric), where the PDA process is performed at a PDA soak temperature of between about 80-150 degrees Celsius in a nitrogen (N₂) ambient. The PDA process may have the effect of filling oxide vacancies, thereby reducing oxide trapping centers. In some cases, the reduction of traps may be accomplished by use of a TiN layer (e.g., such as a TiN capping layer) to reduce oxygen absorption into the gate dielectric and reduce oxide defects.

In various embodiments, the current path may be moved a distance away from the transistor channel-to-gate dielectric interface by doping the transistor channel (e.g., semiconductor layer) near the channel-to-gate dielectric interface. In an example, the transistor channel may be doped using an ion implantation process, a diffusion doping process, an ALD deposition of a doped layer followed by a drive-in anneal process, a plasma doping (PLAD) process, or using another appropriate doping process. In particular, the doping process may be used to introduce a dopant species (e.g., such as an N-type dopant species, a P-type dopant species, positively charged ions, or negatively charged ions) in the semiconductor channel layer near the channel-to-gate dielectric interface that is of the same type as the transistor within which it is being introduced (e.g., an N-type dopant species or negatively charged ions for an N-type transistor and a P-type dopant species or positively charged ions for a P-type transistor). As a result, in some examples, the transistor may operate as a buried-channel transistor, where during operation current in the transistor will flow in a bulk portion of the transistor (e.g., within a bulk portion of a fin structure of a FinFET device) between a source and a drain, and away from the channel-to-gate dielectric interface. In some embodiments, when the dopant species includes negatively charged ions introduced into the gate dielectric near the channel-to-gate dielectric interface of an N-type transistor, electrons flowing in the transistor channel may be repelled from the channel-to-gate dielectric interface by the negatively charged ions. In another example, when the dopant species includes positively charged ions introduced into the gate dielectric near the channel-to-gate dielectric interface of a P-type transistor, holes flowing in the transistor channel may be repelled from the channel-to-gate dielectric interface by the positively charged ions. Regardless of the method by which the current path is moved a distance away from the transistor channel-to-gate dielectric interface, charge trapping of carriers at the channel-to-gate dielectric interface, as well as the associated flicker noise, can be reduced. Other embodiments and advantages will be evident to those skilled in the art upon reading the present disclosure.

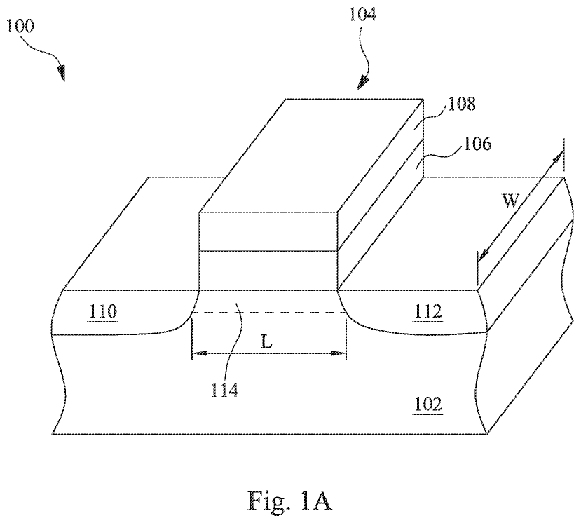

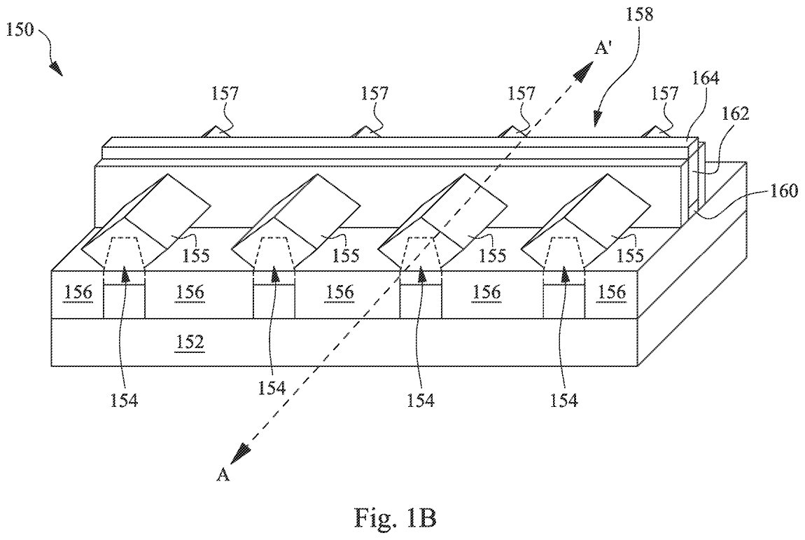

Referring now to the example of FIG. 1A, illustrated therein is an MOS transistor 100, providing an example of merely one device type which may include embodiments of the present disclosure. It is understood that the exemplary transistor 100 is not meant to be limiting in any way, and those of skill in the art will recognize that embodiments of the present disclosure may be equally applicable to any of a variety of other device types, such as those described above. The transistor 100 is fabricated on a substrate 102 and includes a gate stack 104. The substrate 102 may be a semiconductor substrate such as a silicon substrate. The substrate 102 may include various layers, including conductive or insulating layers formed on the substrate 102. The substrate 102 may include various doping configurations depending on design requirements as is known in the art. The substrate 102 may also include other semiconductors such as germanium, silicon carbide (SiC), silicon germanium (SiGe), or diamond. Alternatively, the substrate 102 may include a compound semiconductor and/or an alloy semiconductor. Further, in some embodiments, the substrate 102 may include an epitaxial layer (epi-layer), the substrate 102 may be strained for performance enhancement, the substrate 102 may include a silicon-on-insulator (SOI) structure, and/or the substrate 102 may have other suitable enhancement features.

The gate stack 104 includes a gate dielectric 106 and a gate electrode 108 disposed on the gate dielectric 130. In some embodiments, the gate dielectric 106 may include an interfacial layer such as silicon oxide layer (SiO₂) or silicon oxynitride (SiON), where such interfacial layer may be formed by chemical oxidation, thermal oxidation, atomic layer deposition (ALD), chemical vapor deposition (CVD), and/or other suitable method. In some examples, the gate dielectric 106 includes a high-k dielectric layer such as hafnium oxide (HfO₂). Alternatively, the high-k dielectric layer may include other high-k dielectrics, such as TiO₂, HfZrO, Ta₂O₃, HfSiO₄, ZrO₂. ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), Al₂O₃, Si₃N₄, oxynitrides (SiON), combinations thereof, or other suitable material. High-K gate dielectrics, as used and described herein, include dielectric materials having a high dielectric constant, for example, greater than that of thermal silicon oxide (˜3.9). In still other embodiments, the gate dielectric 106 may include silicon dioxide or other suitable dielectric. The gate dielectric 106 may be formed by ALD, physical vapor deposition (PVD), CVD, oxidation, and/or other suitable methods. In some embodiments, the gate electrode 108 may be deposited as part of a gate first or gate last (e.g., replacement gate) process. In various embodiments, the gate electrode 108 includes a conductive layer such as W. Ti, TiN, TiAl, TiAlN, Ta, TaN, WN, Re, Ir, Ru, Mo, Al, Cu, Co, CoSi, Ni, NiSi, combinations thereof, and/or other suitable compositions. In some examples, the gate electrode 108 may include a first metal material for an N-type transistor and a second metal material for a P-type transistor. Thus, the transistor 100 may include a dual work-function metal gate configuration. For example, the first metal material (e.g., for N-type devices) may include metals having a work function substantially aligned with a work function of the substrate conduction band, or at least substantially aligned with a work function of the conduction band of a channel region 114 of the transistor 100. Similarly, the second metal material (e.g., for P-type devices) may include metals having a work function substantially aligned with a work function of the substrate valence band, or at least substantially aligned with a work function of the valence band of the channel region 114 of the transistor 100. Thus, the gate electrode 104 may provide a gate electrode for the transistor 100, including both N-type and P-type devices. In some embodiments, the gate electrode 108 may alternately or additionally include a polysilicon layer. In various examples, the gate electrode 108 may be formed using PVD, CVD, electron beam (e-beam) evaporation, and/or other suitable process. In some embodiments, sidewall spacers are formed on sidewalls of the gate stack 104. Such sidewall spacers may include a dielectric material such as silicon oxide, silicon nitride, silicon carbide, silicon oxynitride, or combinations thereof.

The transistor 100 further includes a source region 110 and a drain region 112 each formed within the semiconductor substrate 102, adjacent to and on either side of the gate stack 104. In some embodiments, the source and drain regions 110, 112 include diffused source/drain regions, ion implanted source/drain regions, epitaxially grown regions, or a combination thereof. The channel region 114 of the transistor 100 is defined as the region between the source and drain regions 110, 112 under the gate dielectric 106, and within the semiconductor substrate 102. The channel region 114 has an associated channel length “L” and an associated channel width “W”. In operation, an electric current (e.g., a transistor drive current) flows between the source and drain regions 110, 112 through the channel region 114. The amount of drive current developed for a given bias voltage (e.g., applied to the gate electrode 108 or between the source and drain regions 110, 112) is a function of, among others, the mobility of the material used to form the channel region 114. In some examples, the channel region 114 includes silicon (Si) and/or a high-mobility material such as germanium, which may be epitaxially grown, as well as any of the plurality of compound semiconductors or alloy semiconductors as known in the art. High-mobility materials include those materials with electron and/or hole mobility greater than silicon (Si), which has an intrinsic electron mobility at room temperature (300 K) of around 1350 cm²/V-s and an intrinsic hole mobility at room temperature (300 K) of around 480 cm²/V-s.

Referring to FIG. 1B, illustrated therein is a multi-gate device 150, providing an example of an alternative device type which may include embodiments of the present disclosure. By way of example, the multi-gate device 150 includes one or more multi-gate field-effect transistors (FETs). In various embodiments, the multi-gate device 150 may include a FinFET device or a GAA device. The multi-gate device 150 includes a substrate 152, at least one fin element 154 extending from the substrate 152, isolation regions 156, and a gate structure 158 disposed on and around the fin-element 154. The substrate 152 may be a semiconductor substrate such as a silicon substrate. In various embodiments, the substrate 152 may be substantially the same as the substrate 102 and may include one or more of the materials used for the substrate 102, as described above.

The fin-element 154, like the substrate 152, may include one or more epitaxially-grown layers, and may comprise silicon or another elementary semiconductor, such as germanium; a compound semiconductor including silicon carbide, gallium arsenide, gallium phosphide, indium phosphide, indium arsenide, and/or indium antimonide; an alloy semiconductor including SiGe, GaAsP, AlInAs, AlGaAs, InGaAs, GaInP, and/or GaInAsP; or combinations thereof. The fin elements 154 may be fabricated using suitable processes including photolithography and etch processes. The photolithography process may include forming a photoresist layer (resist) overlying the substrate (e.g., on a silicon layer), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate while an etch process forms recesses into the silicon layer, thereby leaving an extending fin 154. The recesses may be etched using a dry etch (e.g., chemical oxide removal), a wet etch, and/or other suitable processes. Numerous other embodiments of methods to form the fins 154 on the substrate 152 may also be used. It is also noted that when the multi-gate device 150 includes a FinFET device, the fins 154 may include a continuous fin of substantially uniform composition, and when the multi-gate device 150 includes a GAA device, the fins 154 may include a plurality of channels disposed in a plurality of semiconductor channel layers interposed by portions of the gate structure 158.

Each of the plurality of fins 154 also include a source region 155 and a drain region 157 where the source/drain regions 155, 157 are formed in, on, and/or surrounding the fin 154. The source/drain regions 155, 157 may be epitaxially grown over the fins 154. In addition, a channel region (or multiple channel regions) of a transistor is disposed within the fin 154, underlying the gate structure 158, along a plane substantially parallel to a plane defined by section AA′ of FIG. 1B. In some examples, the channel region of the fin includes a high-mobility material, as described above.

The isolation regions 156 may be shallow trench isolation (STI) features. Alternatively, a field oxide, a LOCOS feature, and/or other suitable isolation features may be implemented on and/or within the substrate 152. The isolation regions 156 may be composed of silicon oxide, silicon nitride, silicon oxynitride, fluorine-doped silicate glass (FSG), a low-k dielectric, combinations thereof, and/or other suitable material known in the art. In an embodiment, the isolation regions 156 are STI features and are formed by etching trenches in the substrate 152. The trenches may then be filled with isolating material, followed by a chemical mechanical polishing (CMP) process. However, other embodiments are possible. In some embodiments, the isolation regions 156 may include a multi-layer structure, for example, having one or more liner layers.

The gate structure 158 includes a gate stack having an interfacial layer 160 formed over the channel region of the fin 154, a gate dielectric layer 162 formed over the interfacial layer 160, and a metal layer 164 formed over the gate dielectric layer 162. In various embodiments, the interfacial layer 160 is substantially the same as the interfacial layer described as part of the gate dielectric 106. In some embodiments, the gate dielectric layer 162 is substantially the same as the gate dielectric 106 and may include high-k dielectrics similar to that used for the gate dielectric 106. Similarly, in various embodiments, the metal layer 164 is substantially the same as the gate electrode 108, described above. In some embodiments, sidewall spacers are formed on sidewalls of the gate structure 158. The sidewall spacers may include a dielectric material such as silicon oxide, silicon nitride, silicon carbide, silicon oxynitride, or combinations thereof.

Each of the transistor 100 and multi-gate device 150 may include one or more embodiments of the present disclosure, which are described in more detail below. However, for the sake of clarity, the discussion that follows is primarily directed to multi-gate devices, such as the multi-gate device 150. As used herein, the term “multi-gate device” is used to describe a device (e.g., a semiconductor transistor) that has at least some gate material disposed on multiple sides of at least one channel of the device. For instance, the multi-gate device may include a FinFET device having gate material disposed on at least three sides of a transistor channel, a GAA device having gate material disposed on at least four sides of a transistor channel, or a FinFET device formed in combination with a GAA device. When the multi-gate device includes a GAA device, the channel regions may be referred to as “nanowires,” which may include channel regions of various geometries (e.g., cylindrical, bar-shaped) and various dimensions.

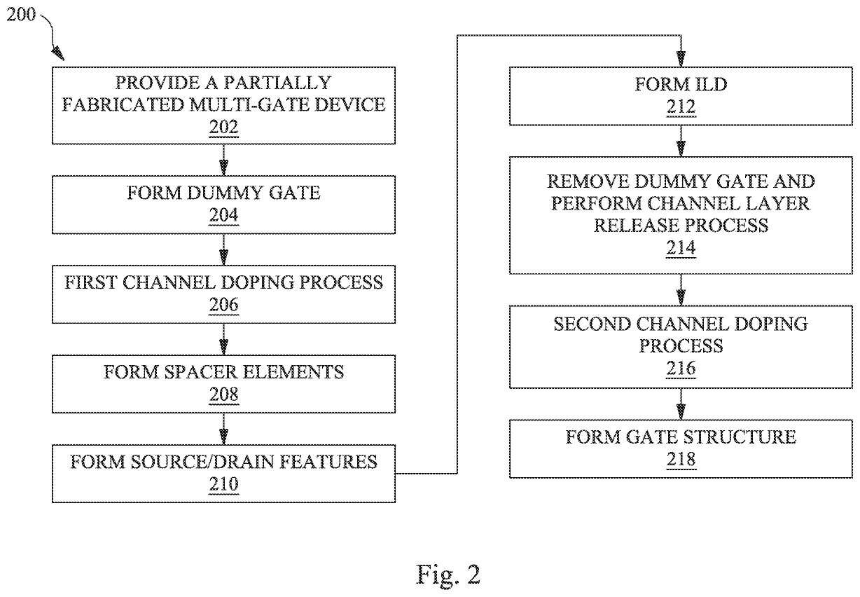

Referring to FIG. 2, illustrated therein is a method 200 of semiconductor fabrication including fabrication of multi-gate devices, including a GAA device 300A and a FinFET device 300B. It is understood that the method 200 includes steps having features of a complementary metal-oxide-semiconductor (CMOS) technology process flow and thus, are only described briefly herein. Additional steps may be performed before, after, and/or during the method 200. It is noted that the semiconductor devices 300A, 300B may include various other devices and features, such as other types of devices such as additional transistors, bipolar junction transistors, resistors, capacitors, inductors, diodes, fuses, static random-access memory (SRAM) and/or other logic circuits, etc., but are simplified for a better understanding of the inventive concepts of the present disclosure. In some embodiments, the semiconductor devices 300A, 300B include a plurality of semiconductor devices (e.g., transistors), including PFETs, NFETs, etc., which may be interconnected. Moreover, it is noted that the process steps of method 200, including any descriptions given with reference to the figures are merely exemplary and are not intended to be limiting beyond what is specifically recited in the claims that follow.

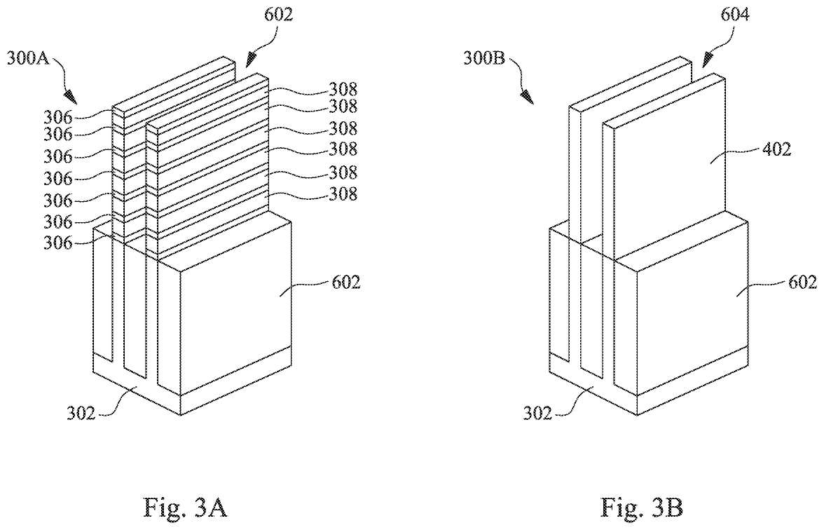

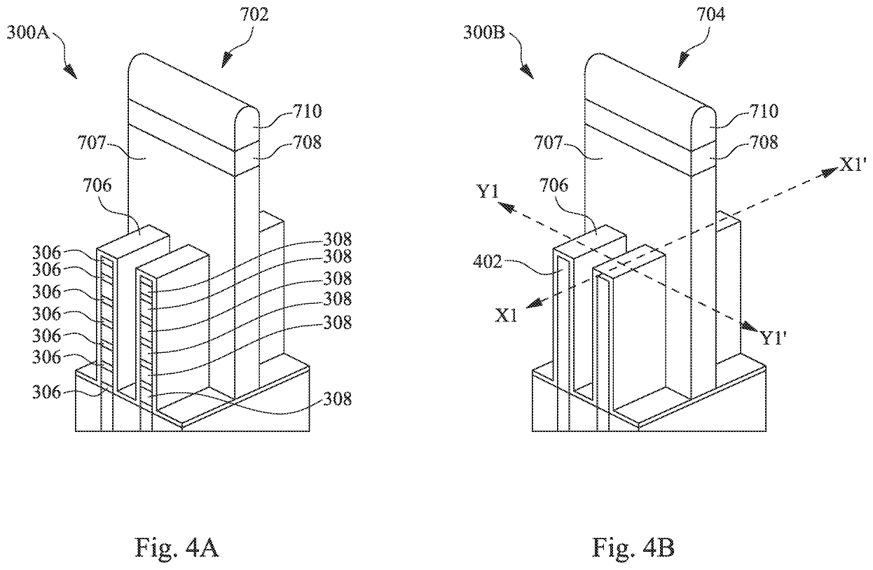

The method 200 begins at block 202 where a partially fabricated multi-gate device is provided. Referring to the example of FIGS. 3A and 3B, in an embodiment of block 202, the partially fabricated multi-gate device may include a partially fabricated GAA device 300A as shown in FIG. 3A, or a partially fabricated FinFET device 300B as shown in FIG. 3B. FIGS. 3A and 3B provide isometric views of the GAA device 300A and the FinFET device 300B, respectively, in accordance with some embodiments. For purposes of this discussion, fabrication processes for each of the GAA device 300A and the FinFET device 300B will be discussed in parallel. However, it will be understood that in various embodiments, one device type or both device types (GAA and/or FinFET devices) may be fabricated on a given substrate. Each of the GAA device 300A and the FinFET device 300B include a substrate 302. In some embodiments, the substrate 302 may be a semiconductor substrate such as a silicon substrate. In various embodiments, the substrate 302 may be substantially the same as the substrates 102, 152 and may include one or more of the materials used for the substrates 102, 152, as described above. In addition, each of the GAA device 300A and the FinFET device 300B may include an N-type device formed in an N-type region of the substrate 302 or a P-type device formed in a P-type region of the substrate 302.

As shown in FIGS. 3A, the GAA device 300A includes fins 602 extending from the substrate 302, where the fins 602 include a substrate portion and epitaxial layers 306 of a first composition interposed by epitaxial layers 308 of a second composition disposed over the substrate portion. The first and second composition can be different. In an embodiment, the epitaxial layers 306 are SiGe and the epitaxial layers 308 are silicon (Si). However, other embodiments are possible including those that provide for a first composition and a second composition having different oxidation rates and/or etch selectivity. The epitaxial layers 308 or portions thereof may form a channel region of the GAA device 300A. For example, the epitaxial layers 308 may be referred to as “nanowires” used to form a channel region of the GAA device 300A. These “nanowires” may also used to form portions of the source/drain features of the GAA device 300A. Again, as the term is used herein, “nanowires” refers to semiconductor layers that are cylindrical in shape as well as other configurations such as, bar-shaped.

It is noted that while seven (7) layers of the epitaxial layer 306 and six (6) layers of the epitaxial layer 308 are illustrated in FIG. 3A, this is for illustrative purposes only and not intended to be limiting beyond what is specifically recited in the claims. It can be appreciated that any number of epitaxial layers can be formed; the number of layers depending on the desired number of channel regions for the GAA device 300A. In some embodiments, the number of epitaxial layers 308 is between 4 and 10.

In some embodiments, the epitaxial layer 306 has a thickness range of about 4-8 nanometers (nm). In some embodiments, the epitaxial layers 306 may be substantially uniform in thickness. However, in some cases, a topmost layer of the epitaxial layers 306 may be thicker than the remaining epitaxial layers 306, for example, to mitigate layer loss that may occur to the topmost layer of the epitaxial layers 306 during a subsequent CMP process. In some embodiments, the epitaxial layer 308 has a thickness range of about 5-8 nm. In some embodiments, the epitaxial layers 308 are substantially uniform in thickness. As described in more detail below, the epitaxial layer 308 may serve as channel region(s) for the subsequently formed GAA device 300A and its thickness chosen based on device performance considerations. The epitaxial layer 306 may serve to define a gap distance between adjacent channel region(s) for the subsequently formed multi-gate device and its thickness chosen based on device performance considerations.

By way of example, epitaxial growth of the epitaxial layers 306, 308 may be performed by a molecular beam epitaxy (MBE) process, a metalorganic chemical vapor deposition (MOCVD) process, and/or other suitable epitaxial growth processes. In some embodiments, the epitaxially grown layers such as, the layers 308 include the same material as the substrate 302. In some embodiments, the epitaxially grown layers 306, 308 include a different material than the substrate 302. As stated above, in at least some examples, the epitaxial layer 306 includes an epitaxially grown silicon germanium (SiGe) layer and the epitaxial layer 308 includes an epitaxially grown silicon (Si) layer. Alternatively, in some embodiments, either of the epitaxial layers 306, 308 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 306, 308 may be chosen based on providing differing oxidation, etch rates, and/or etch selectivity properties. In various embodiments, the epitaxial layers 306, 308 are initially substantially dopant-free (i.e., having an extrinsic dopant concentration from about 0 cm⁻³ to about 1×10¹⁷ cm⁻³), where for example, no intentional doping is performed during the epitaxial growth process. However, as discussed below and in accordance with embodiments of the present disclosure, portions of the epitaxial layers 308 near a surface of the epitaxial layers 308 (e.g., at a channel-to-gate dielectric interface) may be intentionally doped so that the current path (e.g., between source and drain) is moved a distance (e.g., greater than about 2 Angstroms) away from the transistor channel-to-gate dielectric interface. To be sure, in some examples, the portions of the epitaxial layers 308 near the surface of the epitaxial layers 308 may be in situ doped during the epitaxial growth of the epitaxial layers 308.

As shown in FIGS. 3B, the FinFET device 300B includes fins 604 extending from the substrate 302, where the fins 604 include a substrate portion and an epitaxial layer 402 formed over the substrate portion. In some embodiments, the epitaxial layer 402 includes Si or SiGe; however, other embodiments are possible. In embodiments where the epitaxial layer 402 includes SiGe, a percentage of Ge in the SiGe may be between about 0-35%. The epitaxial layer 402 or portions thereof may form a channel region of the FinFET device 300B. The epitaxial layer 402 or portions thereof may also be used to form portions of the source/drain features of the FinFET device 300B, as discussed below.

Similar to the epitaxial layers 306, 308, epitaxial growth of the epitaxial layer 402 may be performed by an MBE process, an MOCVD process, and/or other suitable epitaxial growth processes. In some embodiments, the epitaxial layer 402 may include the same material as the substrate 302. In some embodiments, the epitaxial layer 402 may include a different material than the substrate 302. As stated above, in at least some examples, the epitaxial layer 402 includes an epitaxially grown silicon or silicon germanium (SiGe) layer. Alternatively, in some embodiments, the epitaxial layer 402 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP. AlInAs, AlGaAs, InGaAs, GalnP, and/or GaInAsP, or combinations thereof. In various embodiments, the epitaxial layer 402 is initially substantially dopant-free (i.e., having an extrinsic dopant concentration from about 0 cm⁻³ to about 1×10¹⁷ cm⁻³), where for example, no intentional doping is performed during the epitaxial growth process. However, as discussed below and in accordance with embodiments of the present disclosure, portions of the epitaxial layer 402 near a surface of the epitaxial layer 402 (e.g., at a channel-to-gate dielectric interface) may be intentionally doped so that the current path (e.g., between source and drain) is moved a distance (e.g., greater than about 2 Angstroms) away from the transistor channel-to-gate dielectric interface.

In various embodiments, the fins 602, 604 may be fabricated using suitable processes including photolithography and etch processes, and in a manner substantially similar to that described above with reference to the fins 154 of the multi-gate device 150. Upon formation of the fins 602, 604, trenches may be formed adjacent to and interposing the fins 602, 604. In various embodiments, the trenches may be filled with a dielectric material, which may then be planarized and recessed, to form shallow trench isolation features 602. In some embodiments, the dielectric layer used to fill the trenches may include SiO₂, silicon nitride, silicon oxynitride, fluorine-doped silicate glass (FSG), a low-k dielectric, combinations thereof, and/or other suitable materials known in the art. In various examples, the dielectric layer may be deposited by a CVD process, a subatmospheric CVD (SACVD) process, a flowable CVD process, an ALD process, a PVD process, and/or other suitable process. In some embodiments, the devices 300A, 300B may be annealed, for example, to improve the quality of the dielectric layer. In some embodiments, the dielectric layer (and thus the STI features 602) may include a multi-layer structure, for example, having one or more liner layers.

As shown in the example of FIGS. 3A and 3B, the STI features 602 are recessed such that the fins 602, 604 extend above the STI features 602. In some embodiments, the recessing process may include a dry etching process, a wet etching process, and/or a combination thereof. In some embodiments, a recessing depth is controlled (e.g., by controlling an etching time) so as to result in a desired height of the exposed upper portion of the fin elements 602, 604. In some embodiments, the height exposes each of the epitaxial layers 306, 308 of the GAA device 300A, and substantially all of the epitaxial layer 402 of the FinFET device 300B.

The method 200 then proceeds to block 204 where a dummy gate structure is formed. While the present discussion is directed to a replacement gate (gate-last) process whereby a dummy gate structure is formed and subsequently replaced, other configurations (e.g., such as gate-first) may be possible. With reference to FIGS. 4A and 4B, in an embodiment of block 204, a gate stack 702 is formed over the fins 602 of the GAA device 300A, and a gate stack 704 is formed over the fins 604 of the FinFET device 300B. FIGS. 4A and 4B provide isometric views of the GAA device 300A and the FinFET device 300B, respectively, in accordance with some embodiments. In an embodiment, the gate stacks 702, 704 are dummy (sacrificial) gate stacks that are subsequently removed and replaced, as discussed below.

In some embodiments, prior to forming the gate stacks 702, 704, a dielectric layer 706 may be optionally formed. In some embodiments, the dielectric layer 706 is deposited over the substrate 302 and over the fins 602, 604, including within trenches between adjacent fins 602, 604. In some embodiments, the dielectric layer 706 may include SiO₂, silicon nitride, a high-K dielectric material or other suitable material. In various examples, the dielectric layer 706 may be deposited by a CVD process, a subatmospheric CVD (SACVD) process, a flowable CVD process, an ALD process, a PVD process, or other suitable process. By way of example, the dielectric layer 706 may be used to prevent damage to the fin elements 602, 604 by subsequent processing (e.g., subsequent formation of the dummy gate).

In some embodiments using a gate-last process, the gate stacks 702, 704 are dummy gate stacks and will be replaced by the final gate stack at a subsequent processing stage of the GAA device 300A and the FinFET device 300B. In particular, the gate stacks 702, 704 may be replaced at a later processing stage by a high-K dielectric layer (HK) and metal gate electrode (MG). In some embodiments, the gate stacks 702, 704 are formed over the substrate 302 and are at least partially disposed over the fin elements 602, 604. Additionally, in various embodiments, the gate stacks 702, 704 may be formed over the dielectric layer 706, which was optionally deposited as described above prior to formation of the gate stacks 702, 704. The portion of the fin elements 602, 604 underlying the gate stacks 702, 704 may be referred to as the channel region. The gate stacks 702. 704 may also define a source/drain region of the fins 602, 604, for example, the regions of the fins 602, 604 adjacent to and on opposing sides of the channel region.

In some embodiments, the gate stacks 702, 704 include a dielectric layer and an electrode layer, both of which are represented by element 707. The gate stacks 702, 704 may also include one or more hard mask layers 708, 710. In some embodiments, the hard mask layer 708 may include an oxide layer, and the hard mask layer 710 may include a nitride layer. In some embodiments, the gate stacks 702, 704 are formed by various process steps such as layer deposition, patterning, etching, as well as other suitable processing steps. In some examples, the layer deposition process includes CVD (including both low-pressure CVD and plasma-enhanced CVD), PVD, ALD, thermal oxidation, e-beam evaporation, or other suitable deposition techniques, or a combination thereof. In forming the gate stack for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods.

In some embodiments, the dielectric layer of the gate stacks 702, 704 includes silicon oxide. Alternatively, or additionally, the dielectric layer of the gate stacks 702, 704 may include silicon nitride, a high-K dielectric material or other suitable material. In some embodiments, the electrode layer of the gate stacks 702, 704 may include polycrystalline silicon (polysilicon). In some embodiments, the oxide of the hard mask layer 708 includes a pad oxide layer that may include SiO₂. In some embodiments, the nitride of the hard mask layer 710 includes a pad nitride layer that may include Si₃N₄, silicon oxynitride or silicon carbide.

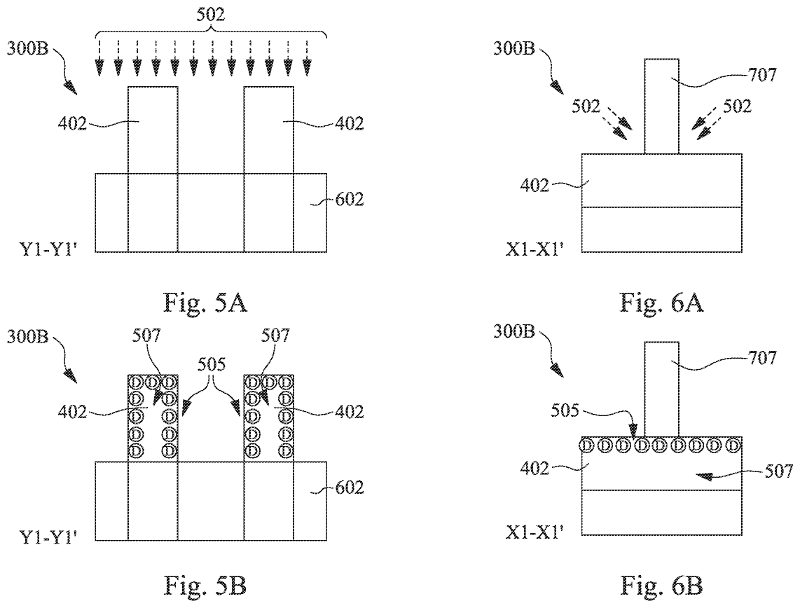

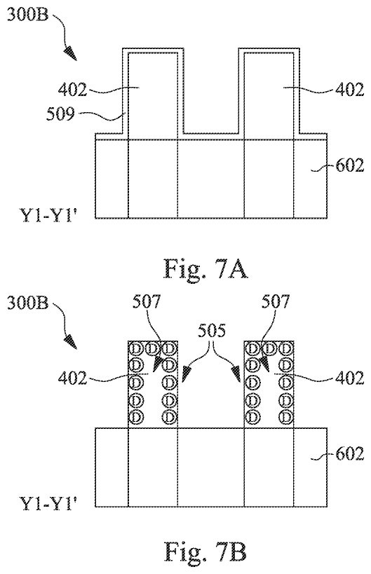

The method 200 then proceeds to block 206 where a first channel doping process is performed. With reference to FIGS. 5A, 5B, 6A, 6B, 7A, 7B, 8A, 8B, and 8B, in an embodiment of block 206, a first channel doping process is performed to the FinFET device 300B. FIGS. 5A/5B/7A/7B provide cross-section views of the FinFET device 300B along a plane parallel to section Y1-Y1′, and FIGS. 6A/6B/8A/8B/8C provide cross-sections views of the FinFET device 300B along a plane parallel to section X1-X1′, as shown in FIG. 4B. In an example, portions of the epitaxial layer 402 near a surface of the epitaxial layer 402 (e.g., near what will become a channel-to-gate dielectric interface) may be intentionally doped so that the current path (e.g., between source and drain) is moved a distance (e.g., greater than about 2 Angstroms) away from the transistor channel-to-gate dielectric interface. Portions of the epitaxial layers 308 of the GAA device 300A (e.g., which form the channels of the GAA device 300A), near the surface of the epitaxial layers 308, may be doped at a later stage of processing, as described further below. It is noted that the dielectric layer 706, while omitted for the sake of clarity in FIGS. 5A, 5B, 6A, 6B, 7A, 7B, 8A, 8B, and 8B, may or may not be present, as described in more detail below.

With reference first to FIGS. 5A/5B/6A/6B, in one embodiment of block 206, an ion implantation process 502 may be performed to form a doped layer 505 along a surface of the epitaxial layer 402, including underneath the gate stack 704 (e.g., underneath the gate dielectric and electrode 707). In various example, the ion implantation process 502 may be performed through the dielectric layer 706, described above, or the ion implantation process 502 may be performed prior to, or without formation of, the dielectric layer 706. In FIGS. 5B/6B, the dopants that form the doped layer 505 are illustrated as a letter ‘D’ within a circle. The implantation energy, implant dose, tilt angle, and rotation are optimized so that the doped layer 505 is formed along the surface of the epitaxial layer 402, as shown. In particular, the implantation process 502 may be optimized to penetrate at least a lower portion of the gate stack 704 in order to form the doped layer 505 beneath the gate stack 704. In some embodiments, a dopant concentration of the doped layer 505 may be in a range of about 1×10¹⁴-1×10¹⁵ cm⁻³, the tilt angle of the implantation process 502 may be in a range of between about 0°-40° (and may include multiple implantations at different tilt angles to form the doped layer 505), and the FinFET device 300B may be rotated during the implantation process 502 to ensure a uniform distribution of dopants. In some cases, during the ion implantation process 502, the FinFET device 300B may be rotated continuously or in discrete steps (e.g., such as about 0-8 discrete steps). It is noted that the ion implantation process 502 may, in some respects, be similar to a lightly doped drain (LDD) implantation process and may in some cases be referred to as an LDD implant even though the resultant doped layer 505 spans the surface of the epitaxial layer 402 including underneath the gate stack 704. Also, in some cases, the ion implantation process 502 may include a plasma doping (PLAD) process.

In various embodiments, the dopant species used to form the doped layer 505 is of the same type (polarity) as the transistor within which it is being introduced (e.g., an N-type dopant species or negatively charged ions for an N-type transistor and a P-type dopant species or positively charged ions for a P-type transistor). Stated another way, the dopant species used to form the doped layer 505 may be of the same type (polarity) as a source/drain doping species of the device within which it is being introduced (e.g., an N-type dopant species or negatively charged ions for a device having an N-type source/drain and a P-type dopant species or positively charged ions for a device having a P-type source/drain). While the dopant species may be of the same type (polarity), it is noted that the dopant concentration of the doped layer 505 will be less than the dopant concentration of the source/drain. By way of example, if the FinFET device 300B is an N-type device, the ion implantation process 502 (and the resulting doped layer 505) may include an N-type dopant species (e.g., a column V element such as phosphorous, arsenic, antimony, and/or a negatively charged ion such as a negatively charged phosphorous ion). In another example, if the FinFET device 300B is a P-type device, the ion implantation process 502 (and the resulting doped layer 505) may include a P-type dopant species (e.g., a column III element such as boron and/or a positively charged ion such as a positively charged boron ion). In such a case, the FinFET device 300B may operate similar to a buried-channel transistor, where during operation current in the FinFET device 300B flows primarily in a bulk portion 507 of the epitaxial layer 402 of FinFET device 300B between a source and a drain, and away from the channel-to-gate dielectric interface. In some embodiments, after formation of the doped layer 505, the FinFET device 300B May be subject to a high thermal budget process (anneal) to remove defects and activate dopants (i.e., to place dopants into substitutional sites).

With reference now to FIGS. 7A/7B/8A/8B/8C, in another embodiment of block 206, an ALD-deposited doped layer 509 may be formed over the epitaxial layer 402, for example, prior to formation of (or without formation of) the dielectric layer 706 and prior to formation of the gate stack 704 (e.g., as shown in FIG. 8A). The ALD-deposited doped layer 509 may be similarly used to form the doped layer 505 along the surface of the epitaxial layer 402, including underneath the gate stack 704, as described above. In various embodiments, the ALD-deposited doped layer 509 may include a dopant species that is of the same type (polarity) as the transistor within which it is being introduced, or of the same type (polarity) as a source/drain doping species of the device within which it is being introduced, as described above. By way of example, if the FinFET device 300B is an N-type device, the ALD-deposited doped layer 509 may include an N-type dopant species (e.g., a column V element such as phosphorous, arsenic, antimony, and/or a negatively charged ion such as a negatively charged phosphorous ion). In another example, if the FinFET device 300B is a P-type device, the ALD-deposited doped layer 509 may include a P-type dopant species (e.g., a column III element such as boron and/or a positively charged ion such as a positively charged boron ion). In some cases, the ALD-deposited doped layer 509 may include an F-based layer (e.g., such as WFx) for N-type devices, and an Al-based layer (e.g., such as TiAl) for P-type devices. After deposition of the ALD-deposited doped layer 509, a drive-in anneal may be performed to cause dopants within the ALD-deposited doped layer 509 to diffuse into the surface of the epitaxial layer 402 to form the doped layer 505 (e.g., as shown in FIG. 8B). After the drive-in anneal, in some cases, any remaining portion of the ALD-deposited layer 509 may be removed using a suitable etching process (e.g., a wet etching process, a dry etching process, or a combination thereof). In the present example, after formation of the doped layer 505, the gate stack 704 may be formed, as described above (e.g., as shown in FIG. 8C). Also, in some cases, rather than use the ALD-deposited doped layer 509, a plasma doping (PLAD) process may be used to form the doped layer 505 prior to formation of the gate stack 704.

The method 200 then proceeds to block 208 where spacer elements are formed. With reference to FIGS. 9A and 9B, in an embodiment of block 208, sidewall spacers 802 are formed on the sidewalls of the gate stacks 702, 704. FIGS. 9A and 9B provide isometric views of the GAA device 300A and the FinFET device 300B, respectively, in accordance with some embodiments. Formation of the sidewall spacers 802 may include depositing a spacer material layer over each of the GAA device 300A and the FinFET device 300B. In some examples, the deposited spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as main spacer walls, liner layers, and the like. By way of example, the spacer material layer may be formed by depositing a dielectric material over the gate stacks 702, 704 using processes such as, CVD process, a subatmospheric CVD (SACVD) process, a flowable CVD process, an ALD process, a PVD process, or other suitable process.

In some embodiments, the deposition of the spacer material layer is followed by an etching back (e.g., anisotropically) of the dielectric spacer material. Referring to the example of FIGS. 9A and 9B, after formation of the spacer material layer, the spacer material layer may be etched-back to expose portions of the fin elements 602, 604 adjacent to and not covered by the gate stacks 702, 704 (e.g., source/drain regions). The spacer layer material may remain on the sidewalls of the gate stacks 702, 704 forming sidewall spacers 802. In some embodiments, etching-back of the spacer material layer may include a wet etch process, a dry etch process, a multiple-step etch process, and/or a combination thereof. The spacer material layer may also be removed from a top surface of the gate stacks 702, 704, as illustrated in FIGS. 9A and 9B.

The method 200 then proceeds to block 210 where source/drain features are formed. Initially, in an embodiment of block 210, after formation of the gate stacks 702, 704 and/or the sidewall spacers 802, the dielectric layer 706 (FIGS. 4A/4B) may be etched-back (if present) to expose portions of the fins 602, 604 not covered by the gate stacks 702, 704 (e.g., for example, in source/drain regions), and including portions of the epitaxial layers 306, 308, and 402. In some examples, the dielectric layer 706 may be etched-back substantially to the underlying STI 602. In some embodiments, etching-back of the dielectric layer 706 may include a wet etch process, a dry etch process, a multiple-step etch process, and/or a combination thereof. Thus, in some embodiments, preserving the dielectric layer 706 during formation of the gate stacks 702, 704 serves to effectively protect the fins 602, 604 during such processing.

Referring again to the example of FIGS. 9A and 9B, in a further embodiment of block 210, source/drain features 804, 806 are formed in source/drain regions adjacent to and on either side of the gate stacks 702, 704. In some embodiments, the source/drain features 804, 806 are formed by epitaxially growing a semiconductor material layer on the exposed fins 602, 604 in the source/drain regions. In various embodiments, the semiconductor material layer grown to form the source/drain features 804, 806 may include Ge. Si, GaAs, AlGaAs, SiGe, GaAsP, SiP, or other suitable material. The source/drain features 804, 806 may be formed by one or more epitaxial (epi) processes. In some embodiments, the source/drain features 804, 806 may be in-situ doped during the epi process. For example, in some embodiments, epitaxially grown SiGe source/drain features may be doped with boron. In some cases, epitaxially grown Si epi source/drain features may be doped with carbon to form Si: C source/drain features, phosphorous to form Si: P source/drain features, or both carbon and phosphorous to form SiCP source/drain features. In some embodiments, the source/drain features 804, 806 are not in-situ doped, and instead an implantation process is performed to dope the source/drain features 804, 806. In some embodiments, formation of the source/drain features 804, 806 may be performed in separate processing sequences for each of an N-type source/drain feature (e.g., for an N-type GAA device 300A or an N-type FinFET device 300B) and a P-type source/drain feature (e.g., for a P-type GAA device 300A or a P-type FinFET device 300B).

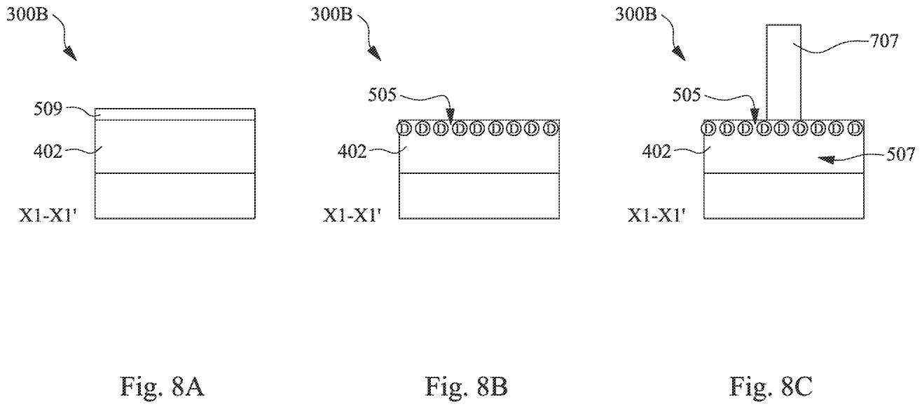

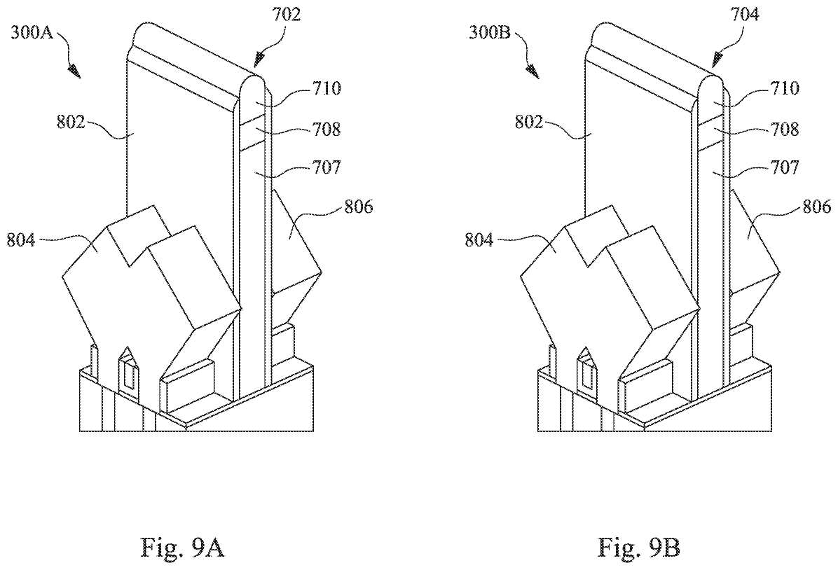

The method 200 then proceeds to block 212 where an inter-layer dielectric (ILD) layer is formed. Referring to the example of FIGS. 10A, 10B, 10C, and 10D, in an embodiment of block 212, an ILD layer 902 is formed over each of the GAA device 300A and the FinFET device 300B. FIGS. 10A and 10B provide isometric views of the GAA device 300A and the FinFET device 300B, respectively, in accordance with some embodiments. FIGS. 10C and 10D provide cross-sections views of the GAA device 300A and the FinFET device 300B, respectively, along a plane parallel to sections X2-X2′, as shown in FIGS. 10A and 10B. In some embodiments, a contact etch stop layer (CESL) is formed over each of the GAA device 300A and the FinFET device 300B prior to forming the ILD layer 902. In some examples, the CESL includes a silicon nitride layer, silicon oxide layer, a silicon oxynitride layer, and/or other materials known in the art. The CESL may be formed by plasma-enhanced chemical vapor deposition (PECVD) process and/or other suitable deposition or oxidation processes. In some embodiments, the ILD layer 902 includes materials such as tetraethylorthosilicate (TEOS) oxide, un-doped silicate glass, or doped silicon oxide such as borophosphosilicate glass (BPSG), fluorosilicate glass (FSG), phosphosilicate glass (PSG), boron doped silicon glass (BSG), and/or other suitable dielectric materials. The ILD layer 902 may be deposited by a PECVD process or other suitable deposition technique. In some embodiments, after formation of the ILD layer 902, each of the GAA device 300A and the FinFET device 300B may be subject to a high thermal budget process to anneal the ILD layer.

In some examples, after depositing the ILD (and/or CESL or other dielectric layers), a planarization process may be performed to expose a top surface of the gate stacks 702, 704 of the GAA device 300A and the FinFET device 300B. For example, a planarization process includes a CMP process which removes portions of the ILD layer 902 (and CESL layer, if present) overlying the gate stacks 702, 704 and planarizes a top surface of each of the GAA device 300A and the FinFET device 300B. In addition, the CMP process may remove the hard mask layers 708, 710 overlying the gate stacks 702, 704 to expose the underlying electrode layer, such as a polysilicon electrode layer, of the dummy gate.

The method 200 proceeds to block 214 where the dummy gate (see block 204) is removed and a channel layer release process is performed if needed (e.g., as needed for fabrication of the GAA device 300A). Referring to the example of FIGS. 10A, 10B, 10C. 10D, 10E, and 10F, in an embodiment of block 214, the electrode layer and dielectric layer of the dummy gate stacks 702, 704 over each of the GAA device 300A and the FinFET device 300B are removed, and a channel layer release process is performed to the GAA device 300A to release the semiconductor channel layers (e.g., the epitaxial layers 308). FIGS. 10E and 10F provide cross-sections views of the GAA device 300A and the FinFET device 300B, respectively, along a plane parallel to sections Y2-Y2′, as shown in FIGS. 10A and 10B.

In some embodiments, an electrode layer (e.g., such as a polysilicon gate electrode) of the dummy gate stacks 702, 704 over each of the GAA device 300A and the FinFET device 300B may initially be removed, by suitable etching processes. After removal of the dummy electrode layer, an etching process is performed to etch the dummy dielectric layer of the dummy gate stacks 702, 704 over each of the GAA device 300A and the FinFET device 300B. Stated another way, removal of the dummy gate in block 214 may include removal of the element 707 (which includes the dummy dielectric layer and electrode layer) from the gate stacks 702, 704 of each of the GAA device 300A and the FinFET device 300B. In some examples, the etching processes may include a wet etch, a dry etch, or a combination thereof.

After removing the dummy gate from the GAA device 300A and the FinFET device 300B, in some examples and in an embodiment of block 214, a channel release process is performed to the GAA device 300A, where the epitaxial layers 306 (dummy layers) in the channel region of the GAA device 300A may be selectively removed (e.g., using a selective etching process), while the epitaxial layers 308 (semiconductor channel layers) remain unetched. In embodiments, the selected epitaxial layer(s) are removed from the fins 602 through a trench provided by the removal of the dummy gate of the GAA device 300A. In some embodiments, the selective etching process may include a selective wet etching process. In some cases, the selective wet etching includes ammonia and/or ozone. As merely one example, the selective wet etching process includes tetra-methyl ammonium hydroxide (TMAH). In some embodiments, the selective etching process may include a dry, plasma-free etching process performed using a CERTAS® Gas Chemical Etch System, available from Tokyo Electron Limited, Tokyo, Japan.

It is noted that as a result of the selective removal of the epitaxial layers 306 (dummy layers), gaps 1002 are formed between the adjacent semiconductor channel layers (the epitaxial layers 308) in the channel region of the GAA device 300A, as illustrated in FIGS. 10A, 10C, and 10E. By way of example, the gaps 1002 may serve to expose surfaces of the epitaxial layers 308, upon which one or more layers of a gate structure will be formed. For instance, as described in more detail below, portions of gate structures (e.g., including a metal gate stack having an interfacial layer, a high-K dielectric layer, and one or more metal electrode layers) will be formed within the gaps 1002 between adjacent semiconductor channel layers (the epitaxial layers 308). In some embodiments, after removing the dummy layers (the epitaxial layers 306), and prior to forming the portions of the gate structures, a sheet trim process (e.g., an etching process) may be performed to modify a profile of the semiconductor channel layers (e.g., the epitaxial layers 308) to achieve desired dimensions and/or desired shapes (e.g., cylindrical-shaped (e.g., nanowire), rectangular-shaped (e.g., nanobar), sheet-shaped (e.g., nanosheet), etc.) of the semiconductor channel layers (the epitaxial layers 308). Thus, after block 214, portions of the semiconductor channel layers (the epitaxial layers 308) used to form the channel region of the GAA device 300A, and portions of the epitaxial layer 402 used to form the channel region of FinFET device 300B, are exposed.

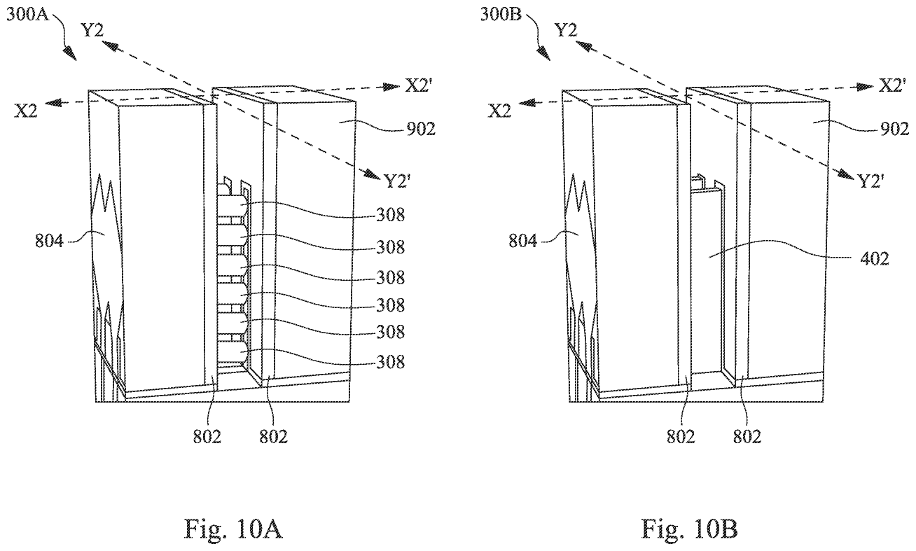

The method 200 then proceeds to block 216 where a second channel doping process is performed. With reference to FIGS. 11A and 11B, in an embodiment of block 216, a second channel doping process is performed to the GAA device 300A. FIGS. 11A and 11B provide enlarged views of a portion 1015 of the GAA device 300A, as shown in FIG. 10E. In an example, portions of the epitaxial layers 308 (e.g., the semiconductor channel layers) near a surface of the epitaxial layers 308 (e.g., near what will become a channel-to-gate dielectric interface) may be intentionally doped so that the current path (e.g., between source and drain) is moved a distance (e.g., greater than about 2 Angstroms) away from the transistor channel-to-gate dielectric interface.

As shown in FIG. 11A, an ALD-deposited doped layer 1109 may be formed over each of the epitaxial layers 308, for example, after the channel release process of block 214. The ALD-deposited doped layer 1109 may be substantially the same as the ALD-deposited doped layer 509, described above. The ALD-deposited doped layer 1109 may thus be used to form a doped layer 1105, which may be similar to the doped layer 505, along the surface of each of the epitaxial layers 308. In various embodiments, the ALD-deposited doped layer 1109 may include a dopant species that is of the same type (polarity) as the transistor within which it is being introduced, or of the same type (polarity) as a source/drain doping species of the device within which it is being introduced, as described above. While the dopant species may be of the same type (polarity), it is noted that the dopant concentration of the doped layer 1105 will be less than the dopant concentration of the source/drain. By way of example, if the GAA device 300A is an N-type device, the ALD-deposited doped layer 1109 may include an N-type dopant species (e.g., a column V element such as phosphorous, arsenic, antimony, and/or a negatively charged ion such as a negatively charged phosphorous ion). In another example, if the GAA device 300A is a P-type device, the ALD-deposited doped layer 1109 may include a P-type dopant species (e.g., a column III element such as boron and/or a positively charged ion such as a positively charged boron ion). In some cases, the ALD-deposited doped layer 1109 may include an F-based layer (e.g., such as WFx) for N-type devices, and an Al-based layer (e.g., such as TiAl) for P-type devices. After deposition of the ALD-deposited doped layer 1109, a drive-in anneal may be performed to cause dopants within the ALD-deposited doped layer 1109 to diffuse into the surface of each of the epitaxial layers 308 to form the doped layer 1105 (e.g., as shown in FIG. 11B). After the drive-in anneal, in some cases, any remaining portion of the ALD-deposited layer 1109 may be removed using a suitable etching process (e.g., a wet etching process, a dry etching process, or a combination thereof). As a result of forming the doped layer 1105, and in some embodiments, the GAA device 300A may operate similar to a buried-channel transistor, where during operation current in the GAA device 300A flows primarily in a bulk portion 1107 of each of the epitaxial layers 308 of GAA device 300A between a source and a drain, and away from the channel-to-gate dielectric interface. In some cases, rather than use the ALD-deposited doped layer 1109, a plasma doping (PLAD) process may be used to form the doped layer 1105.

The method 200 then proceeds to block 218 where a gate structure is formed for each of the GAA device 300A and the FinFET device 300B. As described in more detail below, the gate structure may include a gate dielectric and a metal gate formed over the gate dielectric. In some embodiments, the gate structure may form the gate associated with the plurality of semiconductor channels (epitaxial layers 308) of the GAA device 300A, as well as the gate associated with the semiconductor channel provided by the epitaxial layer 402 in the channel region of the FinFET device 300B.

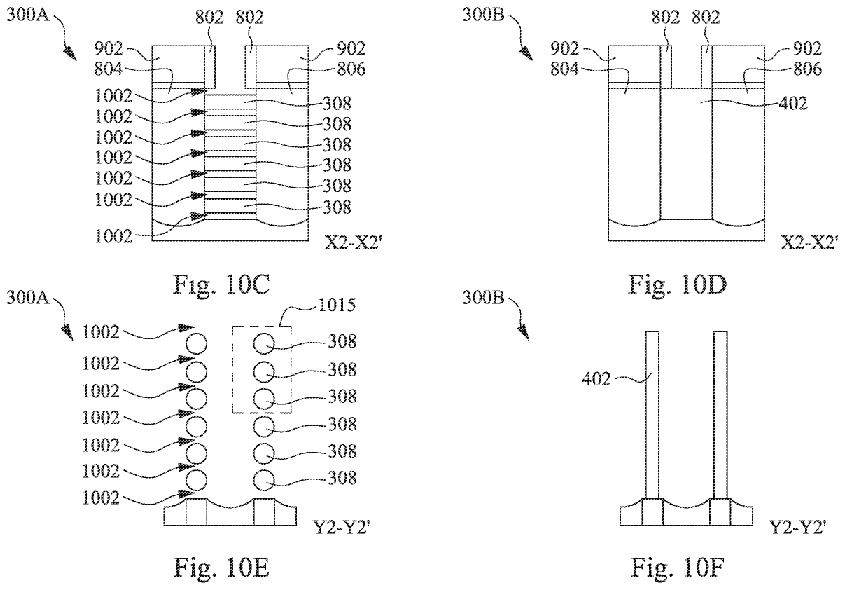

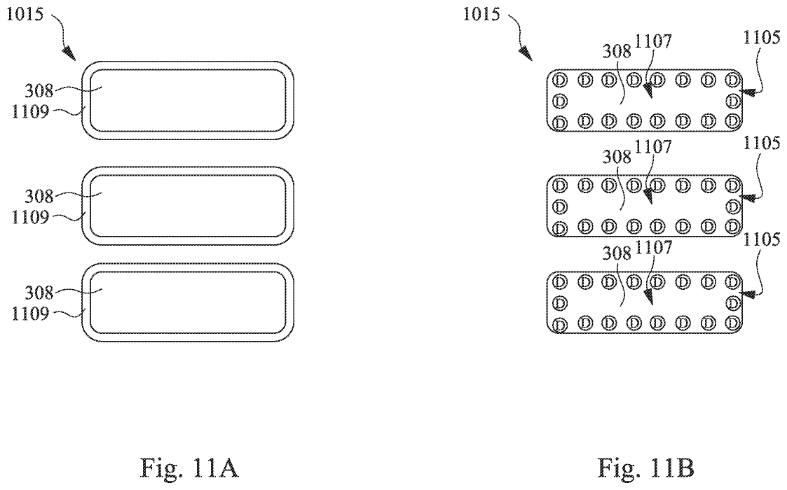

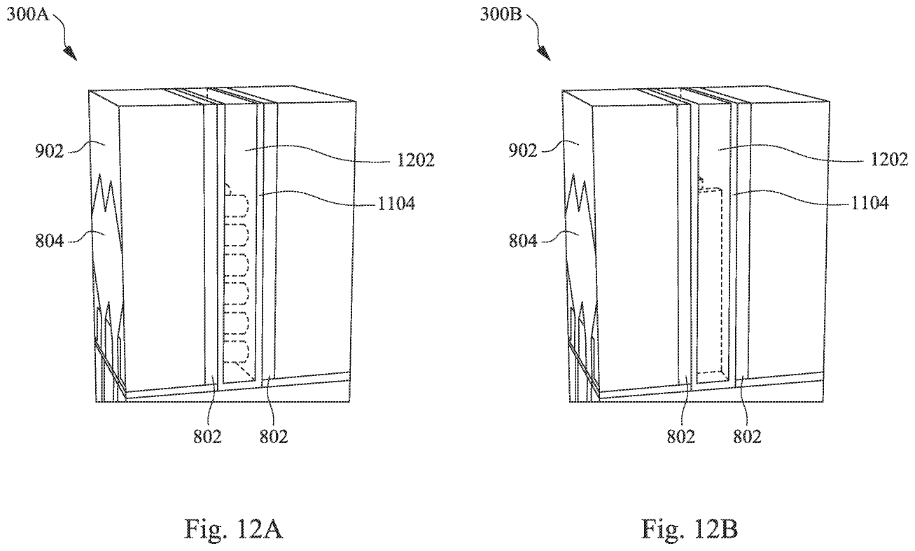

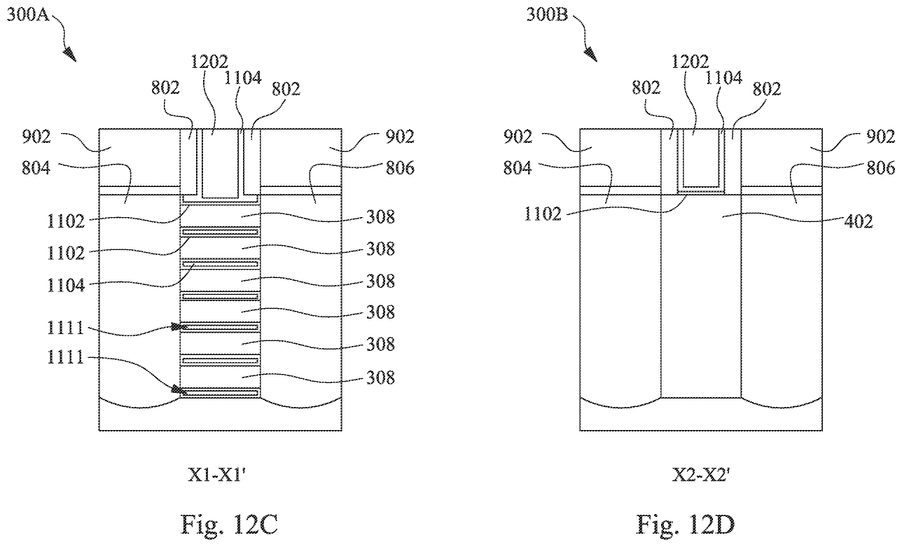

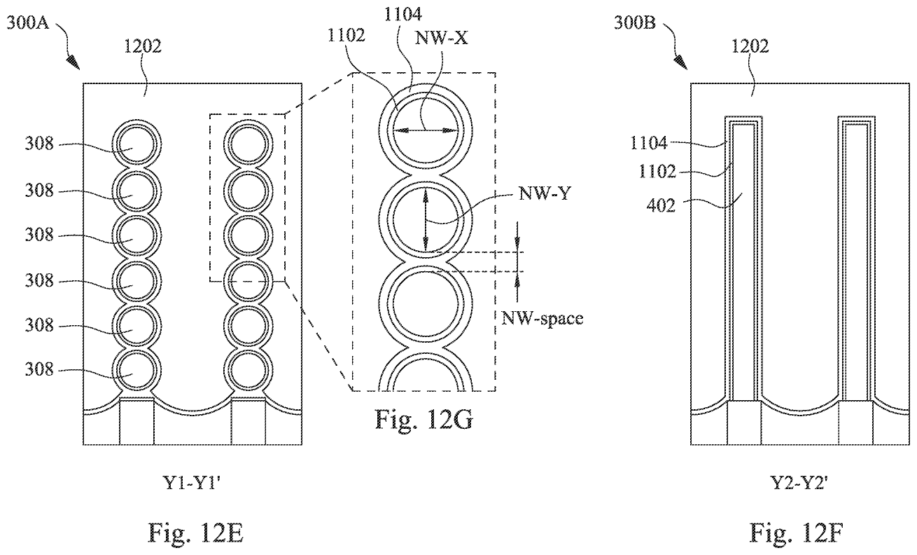

Referring to the example of FIGS. 12A, 12C, and 12E, in an embodiment of block 218, a gate dielectric is formed within the trench of the GAA device 300A provided by the removal of the dummy gate and the channel release process, described above with reference to block 214. FIG. 12A provides an isometric view of the GAA device 300A, in accordance with some embodiments. FIG. 12C provides a cross-section view of the GAA device 300A along a plane parallel to section X2-X2′, as shown in FIG. 10A. FIG. 12E provides a cross-sections view of the GAA device 300A along a plane parallel to section Y2-Y2′, as shown in FIG. 10A. In various embodiments, the gate dielectric includes an interfacial layer (IL) 1102 and a high-K gate dielectric layer 1104 formed over the interfacial layer. High-K gate dielectrics, as used and described herein, include dielectric materials having a high dielectric constant, for example, greater than that of thermal silicon oxide (˜3.9). The gate dielectric, including the IL 1102 and the high-K gate dielectric layer 1104 over the IL 1102, is also formed within the trench of the FinFET device 300B provided by the removal of the dummy gate, as shown in the example of FIGS. 12B, 12D, and 12F. FIG. 12B provides an isometric view of the FinFET device 300B, in accordance with some embodiments. FIG. 12D provides a cross-section view of the FinFET device 300B along a plane parallel to section X2-X2′, as shown in FIG. 10B. FIG. 12F provides a cross-sections view of the FinFET device 300B along a plane parallel to section Y2-Y2′, as shown in FIG. 10B.

In some embodiments, the interfacial layer 1102 may include a dielectric material such as silicon oxide (SiO₂), HfSiO, or silicon oxynitride (SiON). The interfacial layer may be formed by chemical oxidation, thermal oxidation, ALD, CVD, and/or other suitable method. The high-K gate dielectric layer 1104 may include a high-K dielectric layer such as hafnium oxide (HfO₂). Alternatively, the high-K gate dielectric layer 1104 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), Al₂O₃. Si₃N₄, oxynitrides (SiON), combinations thereof, or other suitable material. The high-K gate dielectric layer 1104 may be formed by ALD, PVD, CVD, oxidation, and/or other suitable methods.

In various examples, after deposition of the interfacial layer 1102 and/or after deposition of the high-K gate dielectric layer 1104, a post-deposition anneal (PDA) process may be performed to reduce the interface traps and oxide traps, thereby reducing flicker noise. In some embodiments, the PDA process is performed at a PDA soak temperature of between about 80-150 degrees Celsius in a nitrogen (N₂) ambient for a duration of about 40-80 seconds. The PDA process may have the effect of filling oxide vacancies, thereby reducing oxide trapping centers.

In a further embodiment of block 218, a metal gate including a metal layer 1202 is formed over the gate dielectric of the GAA device 300A and over the gate dielectric of the FinFET device 300B. The metal layer 1202 may include a metal, metal alloy, or metal silicide. Additionally, the formation of the gate dielectric/metal gate stack may include depositions to form various gate materials, one or more liner layers, and one or more CMP processes to remove excessive gate materials and thereby planarize a top surface of the GAA device 300A and the FinFET device 300B. In some examples, after deposition of the metal layer 1202, an optional post-metallization anneal (PMA) process may be performed to further reduce the interface traps and oxide traps, thereby reducing flicker noise.

In some embodiments, the metal layer 1202 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the metal layer 1202 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In at least some cases, the metal layer 1202 may include a thick capping layer (e.g., such as a TiN capping layer), having a thickness of between about 10-80 Angstroms, formed over the gate dielectric to reduce oxygen absorption into the gate dielectric and reduce oxide defects, thereby also reducing flicker noise. In some examples, the thick capping layer may include a TiN capping layer with an in-situ silane pretreatment process (TiN-iSP) to form high-quality Si on the TiN capping layer, rather than potentially absorbing oxygen via a thermal process. In various embodiments, the metal layer 1202 may be formed by ALD, PVD, CVD, e-beam evaporation, or other suitable process. Further, the metal layer 1202 may be formed separately for N-type and P-type transistors which may use different metal layers. In various embodiments, a CMP process may be performed to remove excessive metal from the metal layer 1202, and thereby provide a substantially planar top surface of the metal layer 1202. In addition, the metal layer 1202 may provide an N-type or P-type work function, may serve as a gate electrode of the GAA device 300A and the FinFET device 300B, and in at least some embodiments, the metal layer 1202 may include a polysilicon layer. With respect to the GAA device 300A, the gate structure includes portions that interpose each of the epitaxial layers 308, which each form channels of the GAA device 300A.

It is noted that the GAA device 300 is illustrated as not including an inner spacer layer at lateral ends 1111 of the portions of the gate structure disposed between adjacent epitaxial layers 308 (e.g., as shown in FIG. 12C). However, in some cases, the GAA device 300 may include inner spacers, where the source/drain features 804, 806 would be in contact with such inner spacers in addition to contacting the semiconductor channel layers (the epitaxial layers 308). For purposes of the present example as shown in FIG. 12C, the spacing between adjacent epitaxial layers 308 includes merged IL/HK layers (e.g., the interfacial layer 1102 and the high-K gate dielectric layer 1104), without a dedicated inner spacer. As also shown in the example of FIG. 12C, the semiconductor channel layers (the epitaxial layers 308) and the merged IL/HK layers extend beneath the sidewall spacers 802 while abutting (contacting) the source/drain features 804, 806. It is also noted that in some embodiments, the spacing between adjacent nanowires (e.g., between adjacent epitaxial layers 308 in a NW-Y direction, as discussed below) may include merged interfacial layers 1102 without the high-K gate dielectric layer 1104. In such cases, the high-K gate dielectric layer 1104 would still be disposed at least on lateral sides (e.g., in a NW-X direction, discussed below) of the nanowires. Additionally, in some examples, an end of the high-K gate dielectric layer 1104, or an end of the interfacial layer 1102, may be substantially aligned with an outer lateral surface of the sidewall spacers 802 (e.g., the surface of the sidewall spacers 802 that abuts the ILD layer 902), as shown in FIG. 12C.

FIG. 12G provides a zoomed-in cross-section view of a portion of FIG. 12E, which more clearly illustrates the structure and sizes of various aspects of the GAA device 300A. In some embodiments, a nanowire X dimension (NW-X) is equal to about 5-14 nm, and a nanowire Y dimension (NW-Y) is equal to about 5-8 nm. In some cases, the nanowire X dimension (NW-X) is substantially the same as the nanowire Y dimension (NW-Y). By way of example, if the nanowire X dimension (NW-X) is greater than the nanowire Y dimension (NW-Y), then the nanowire structure may instead be referred to as a “nanosheet”. In some cases, a spacing/gap between adjacent nanowires (NW-space) is equal to about 4-8 nm. It is noted that the spacing/gap between adjacent nanowires (NW-space) is substantially equal to the thickness of the epitaxial layer 306, which was previously disposed between adjacent nanowires, and which was removed at block 214, as discussed above. In some cases, the thickness of the epitaxial layer 306, and thus the resulting spacing/gap between adjacent nanowires, may be chosen to provide a desired thickness of the merged interfacial layer or merged interfacial layer/high-K gate dielectric layer between the adjacent nanowires, to provide complete gap fill between adjacent nanowires that also extends beneath the sidewall spacers 802, and/or to provide a desired number of channel regions for the GAA device 300A (e.g., a smaller spacing between adjacent nanowires may provide for additional epitaxial layers 308, which form the channel regions for the GAA device 300A). In some embodiments, the IL layer 1102 has a thickness of about 0.5-1.5 nm, and the high-K gate dielectric layer 1104 has a thickness of about 1-3 nm.

Each of the GAA device 300A and the FinFET device 300B may undergo further processing to form various features and regions known in the art. For example, subsequent processing may form contact openings, contact metal, as well as various contacts/vias/lines and multilayer interconnect features (e.g., metal layers and interlayer dielectrics) on the substrate 302, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be replaced or eliminated in accordance with various embodiments of the method 200.

With respect to the description provided herein, the present disclosure provides methods and structures for reducing noise (e.g., such as flicker noise) for advanced transistor structures. Generally, the disclosed embodiments may effectively reduce flicker noise by improving (reducing) the density of interface traps and oxide traps, as well as by modulating a transistor channel current path (e.g., a current path between a source and a drain of the transistor) such that the current path is a distance away from the transistor channel-to-gate dielectric interface, thereby minimizing the occurrence of charge trapping at the channel-to-gate dielectric interface. In some embodiments, the reduction of traps may be accomplished by use of PDA process and/or by use of a thick TiN capping layer to reduce oxygen absorption into the gate dielectric. In various embodiments, the current path may be moved a distance away from the transistor channel-to-gate dielectric interface by doping the transistor channel (e.g., semiconductor layer) near the channel-to-gate dielectric interface. In an example, the transistor channel may be doped using an ion implantation process, a diffusion doping process, an ALD deposition of a doped layer followed by a drive-in anneal process, a plasma doping (PLAD) process, or using another appropriate doping process. In particular, the doping process may be used to introduce a dopant species (e.g., such as an N-type dopant species, a P-type dopant species, positively charged ions, or negatively charged ions) in the semiconductor channel layer near the channel-to-gate dielectric interface that is of the same type as the transistor within which it is being introduced. As a result, and during operation, current in the transistor will flow in a bulk portion of the transistor between a source and a drain, and away from the channel-to-gate dielectric interface, such that charge trapping of carriers at the channel-to-gate dielectric interface and the associated flicker noise is reduced. Those of skill in the art will readily appreciate that the methods and structures described herein may be applied to a variety of other semiconductor devices to advantageously achieve similar benefits from such other devices without departing from the scope of the present disclosure.

Thus, one of the embodiments of the present disclosure described a method of fabricating a semiconductor device including providing a first fin extending from a substrate. In some embodiments, the method further includes forming a first gate stack over the first fin. In various examples, the method further includes forming a first doped layer along a surface of the first fin including beneath the first gate stack. In some cases, a first dopant species of the first doped layer is of a same polarity as a second dopant species of a source/drain feature of the semiconductor device.

In another of the embodiments, discussed is a method of fabricating a multi-gate semiconductor device including providing a fin extending from a substrate. In some embodiments, the fin includes a plurality of first epitaxial layers interposed by a plurality of second epitaxial layers. In some examples, the method further includes selectively removing the second epitaxial layers to form gaps between adjacent ones of the plurality of first epitaxial layers and expose surfaces of the plurality of first epitaxial layers. In some embodiments, the method further includes forming a first doped layer over the exposed surfaces of the plurality of first epitaxial layers. In some cases, the method further includes performing a drive-in anneal to cause dopants within the first doped layer to diffuse into the surfaces of the plurality of first epitaxial layers to form a second doped layer along the surfaces of the plurality of first epitaxial layers. In some examples, the method further includes after performing the drive-in anneal, removing a remaining portion of the first doped layer.

In yet another of the embodiments, discussed is a multi-gate semiconductor device including a first fin having a plurality of silicon epitaxial layers. In some embodiments, each of the plurality of silicon epitaxial layers includes a first doped layer along a surface of the silicon epitaxial layer, and the first doped layer has a first polarity type and a first dopant concentration. In some cases, the multi-gate semiconductor device further includes a first gate structure over a channel region of the first fin, where a portion of the first gate structure is disposed between adjacent layers of the plurality of silicon epitaxial layers. In some examples, the multi-gate semiconductor device further includes a first epitaxial source/drain feature adjacent to the channel region of the first fin, where the first epitaxial source/drain feature has a second polarity type the same as the first polarity type, and where the first epitaxial source/drain feature has a second dopant concentration greater than the first dopant concentration.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
providing a first fin extending from a substrate;
forming a first gate stack over the first fin; and
forming a first doped layer along a surface of the first fin including beneath the first gate stack;
wherein a first dopant species of the first doped layer is of a same polarity as a second dopant species of a source/drain feature of the semiconductor device.

2. The method of claim 1, wherein a first dopant concentration of the first doped layer is less than a second dopant concentration of the source/drain feature.

3. The method of claim 1, wherein the first doped layer causes a current path of the semiconductor device to be moved a distance away from a channel-to-gate dielectric interface.

4. The method of claim 1, wherein the forming the first doped layer includes performing an ion implantation process into the surface of the first fin, and wherein the ion implantation process penetrates at least a lower portion of the first gate stack to form the first doped layer beneath the first gate stack.

5. The method of claim 1, wherein the forming the first doped layer includes:
prior to forming the first gate stack, forming an atomic layer deposition (ALD)-deposited doped layer over the first fin;
after forming the ALD-deposited doped layer, performing a drive-in anneal to cause dopants within the ALD-deposited doped layer to diffuse into the surface of the first fin to form the first doped layer; and
after performing the drive-in anneal, removing a remaining portion of the ALD-deposited doped layer.

6. The method of claim 5, wherein the first gate stack is formed over the first fin after the remaining portion of the ALD-deposited doped layer is removed.

7. The method of claim 1, wherein the forming the first doped layer includes performing a plasma doping (PLAD) process prior to forming the first gate stack.

8. The method of claim 1, wherein the second dopant species of the source/drain feature includes an N-type dopant species, and wherein the first dopant species of the first doped layer includes at least one of phosphorous, arsenic, antimony, and a negatively charged ion.

9. The method of claim 1, wherein the second dopant species of the source/drain feature includes a P-type dopant species, and wherein the first dopant species of the first doped layer includes at least one of boron and a positively charged ion.

10. The method of claim 1, further comprising:
providing a second fin extending from a substrate, wherein the second fin includes a plurality of semiconductor channel layers having gaps therebetween;
forming an atomic layer deposition (ALD)-deposited doped layer on surfaces of each of the plurality of semiconductor channel layers;
after forming the ALD-deposited doped layer, performing a drive-in anneal to cause dopants within the ALD-deposited doped layer to diffuse into the surfaces of each of the plurality of semiconductor channel layers to form a second doped layer along the surfaces of each of the plurality of semiconductor channel layers; and
after performing the drive-in anneal, removing a remaining portion of the ALD-deposited doped layer.

11. A method of fabricating a multi-gate semiconductor device, comprising:
providing a fin extending from a substrate, wherein the fin includes a plurality of first epitaxial layers interposed by a plurality of second epitaxial layers;
selectively removing the second epitaxial layers to form gaps between adjacent ones of the plurality of first epitaxial layers and expose surfaces of the plurality of first epitaxial layers;
forming a first doped layer over the exposed surfaces of the plurality of first epitaxial layers;
performing a drive-in anneal to cause dopants within the first doped layer to diffuse into the surfaces of the plurality of first epitaxial layers to form a second doped layer along the surfaces of the plurality of first epitaxial layers; and
after performing the drive-in anneal, removing a remaining portion of the first doped layer.

12. The method of claim 11, further comprising forming a gate structure, wherein portions of the gate structure interpose the plurality of first epitaxial layers.

13. The method of claim 11, wherein a dopant species of the second doped layer is of a same polarity as a source/drain feature of the multi-gate semiconductor device.

14. The method of claim 13, wherein a first dopant concentration of the second doped layer is less than a second dopant concentration of the source/drain feature.

15. The method of claim 11, wherein during operation of the multi-gate semiconductor device, the second doped layer causes current to flow in a bulk portion of the plurality of first epitaxial layers a distance away from a channel-to-gate dielectric interface.

16. The method of claim 11, wherein the multi-gate semiconductor device includes an N-type device, and wherein the dopant species of the second doped layer includes at least one of phosphorous, arsenic, antimony, and a negatively charged ion.

17. The method of claim 11, wherein the multi-gate semiconductor device includes a P-type device, and wherein the dopant species of the second doped layer includes at least one of boron and a positively charged ion.

18. A multi-gate semiconductor device, comprising:
a first fin including a plurality of silicon epitaxial layers, wherein each of the plurality of silicon epitaxial layers includes a first doped layer along a surface of the silicon epitaxial layer, and wherein the first doped layer has a first polarity type and a first dopant concentration;
a first gate structure over a channel region of the first fin, wherein a portion of the first gate structure is disposed between adjacent layers of the plurality of silicon epitaxial layers; and
a first epitaxial source/drain feature adjacent to the channel region of the first fin, wherein the first epitaxial source/drain feature has a second polarity type the same as the first polarity type, and wherein the first epitaxial source/drain feature has a second dopant concentration greater than the first dopant concentration.

19. The multi-gate semiconductor device of claim 18, further comprising:
a second fin including a silicon germanium (SiGe) layer, wherein the SiGe layer includes a second doped layer along a surface of the SiGe layer, and wherein the second doped layer has a third polarity type and a third dopant concentration;
a second gate structure over a channel region of the second fin; and
a second epitaxial source/drain feature adjacent to the channel region of the second fin, wherein the second epitaxial source/drain feature has a fourth polarity type the same as the third polarity type, and wherein the second epitaxial source/drain feature has a fourth dopant concentration greater than the third dopant concentration.

20. The multi-gate semiconductor device of claim 19, wherein a gate-all-around (GAA) device includes the first fin, and wherein a FinFET device includes the second fin.
